(19) United States
(12) Patent Application Publication
(10) Pub. No.: US 2023/0010087 A1
(43) Pub. Date: Jan. 12, 2023

(54) MEMORY ARRAY

(71) Applicant: SONIC STAR GLOBAL LIMITED, Road Town (VG)

(72) Inventors: Chun-Heng CHEN, Taichung City (TW); Chun-Yen LIN, Ji'an Township (TW); Chih-Chieh CHIU, Hsinchu City (TW)

(21) Appl. No.: 17/523,195

(22) Filed: Nov. 10, 2021

Related U.S. Application Data
(60) Provisional application No. 63/219,022, filed on Jul. 7, 2021.

(51) Int. Cl. G11C 15/04

(52) U.S. Cl. CPC G11C 15/04

(57) ABSTRACT

The present disclosure provides a memory array. The memory array includes a first memory cell, a first word line, a second word line, a first bit line, a first complementary bit line, a second bit line, a second complementary bit line, a first sense amplifier, a second sense amplifier and a first logic circuit. When the memory array operates in a binary content-addressable memory (BCAM) mode, during a search operation, a first logic output indicates whether a logic level of the first word line matches a first logic value at a first terminal of a first data storage of the first memory cell, and whether a logic level of the second word line matches a first complementary logic value at a second terminal of the first data storage of the first memory cell.

### CROSS REFERENCE

This application claims priority to U.S. Provisional Application No. 63/219,022, filed on Jul. 7, 2021, the entire disclosure of which is incorporated herein by reference.

### TECHNICAL FIELD

The present disclosure relates to a memory array.

### BACKGROUND

Normally, a memory is searched by inputting an address identifying the memory location at which the required data value is stored. On the contrary, a content-addressable memory (CAM) is a form of memory that can be searched based on the content stored in the memory. More specifically, a data value is input and then the CAM searches its memory locations to see whether that data value is stored. If the data value is stored, then an indication of the location storing the data value is output.

Binary content-addressable memory (BCAM) is a form of content-addressable memory in which each memory cell can store one of two states: “logical high” and “logical low”. Ternary content-addressable memory (TCAM) is another form of content-addressable memory in which each memory cell can store one of three states: “logical high”, “logical low”, and “don't care”. A typical BCAM cell includes 9 transistors while a typical TCAM cell includes 16 transistors. In contrast with the typical BCAM/TCAM cell, a typical dual-port static random access memory (SRAM) only includes 8 transistors. In other words, CAM is larger and takes up more area. Accordingly, there is a need in the art for an improved design to make CAM more compact and flexible in use.

### SUMMARY OF THE INVENTION

Some embodiments of the present disclosure provide a memory array, including: a plurality of first dual-port static random access memory (SRAM) cells, each having a first port, a first complementary port, a second port, and a second complementary port; a first bit line, coupled to the first port of each of the first dual-port SRAM cells; a first complementary bit line, coupled to the first complementary port of each of the first dual-port SRAM cells; a second bit line, coupled to the second port of each of the first dual-port SRAM cells; a second complementary bit line, coupled to the second complementary port of each of the first dual-port SRAM cells; a first comparator, having a first input and a second input, in which the first input of the first comparator is coupled to the first bit line and the second input of the first comparator is coupled to a reference voltage; a second comparator, having a first input and a second input, in which the first input of the second comparator is coupled to the second complementary bit line and the second input of the second comparator is coupled to the reference voltage; and a first logic circuit, arranged for generating a first logic output according to an output of the first comparator and an output of the second comparator.

Some embodiments of the present disclosure provide a memory array, including: a first dual-port static random access memory (SRAM) cell, having a first port, a first complementary port, a second port, and a second complementary port; a second dual-port SRAM cell, having a first port, a first complementary port, a second port, and a second complementary port; a first bit line, coupled to the first port of the first dual-port SRAM cell; a second complementary bit line, coupled to the second complementary port of the first dual-port SRAM cell; a third bit line, coupled to the first port of the second dual-port SRAM cell; a fourth complementary bit line, coupled to the second complementary port of the second dual-port SRAM cell; a first comparator, for comparing a voltage level of the first bit line and a voltage level of a reference voltage; a second comparator, for comparing a voltage level of the second complementary bit line and the voltage level of the reference voltage; a third comparator, for comparing a voltage level of the third bit line and the voltage level of the reference voltage; a fourth comparator, for comparing a voltage level of the fourth complementary bit line and the voltage level of the reference voltage; a first logic gate, arranged for generating a first logic output according to an output of the first comparator and an output of the second comparator; a second logic gate, arranged for generating a second logic output according to an output of the third comparator and an output of the fourth comparator; and a third logic gate, arranged for generating a third logic output according to the output of the second comparator and the output of the third comparator.

Some embodiments of the present disclosure provide a memory array, including: a first memory cell that includes a first data storage element having a first terminal and a second terminal. The first data storage element stores a first logic value at the first terminal and a first complementary logic value at the second terminal. The first memory cell also includes: a first access transistor coupled to the first terminal of the first data storage element; a second access transistor coupled to the second terminal of the first data storage element; a third access transistor coupled to the first terminal of the first data storage element; and a fourth access transistor coupled to the second terminal of the first data storage element. Moreover, the memory array includes a first word line, configured to selectively enable access to the first data storage element through the first access transistor and the second access transistor; a second word line, configured to selectively enable access to the first data storage element through the third access transistor and the fourth access transistor; a first bit line, where the first access transistor is coupled between the first bit line and the first terminal of the first data storage element; a first complementary bit line, where the second access transistor is coupled between the first complementary bit line and the second terminal of the first data storage element; a second bit line, where the third access transistor is coupled between the second bit line and the first terminal of the first data storage element; a second complementary bit line, where the fourth access transistor is coupled between the second complementary bit line and the second terminal of the first data storage element; a first sense amplifier, arranged for generating a first sensed result according to a logic level of the first bit line and a reference voltage; a second sense amplifier, arranged for generating a second sensed result according to a logic level of the second complementary bit line and the reference voltage; and a first logic circuit, arranged for generating a first logic output according to the first sensed result and the second sensed result. When the memory array operates in a dual-port static random access memory (SRAM) mode, the first sensed result indicates the first logic value stored at the first terminal of the first data storage element in response to selection of the first word line during a read operation, and the second sensed result indicates the first complementary logic value stored at the second terminal of the first data storage element in response to selection of the second word line during the read operation. When the memory array operates in a binary content-addressable memory (BCAM) mode and performs a search operation, the first logic output indicates whether a logic level of the first word line matches the first logic value, and whether a logic level of the second word line matches the first complementary logic value. The voltage level of the reference voltage is lower than logical high and higher than logical low.

This application proposes a new memory array architecture that can switch between the SRAM, BCAM and TCAM modes, and has twice the capacity in the SRAM and BCAM modes than in the TCAM mode.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram illustrating a memory array, in accordance with some embodiments of the present disclosure.

FIG. 2 is a schematic circuit diagram illustrating the memory array, in accordance with an embodiment of the present disclosure.

FIG. 3 is a diagram illustrating the search operation of the BCAM mode of the memory array of FIG. 2 when a “match” condition happens.

FIG. 4 is a diagram illustrating the search operation of the BCAM mode of the memory array of FIG. 2 when a “mismatch” condition happens.

FIG. 5 is a diagram illustrating the search operation of the TCAM mode of the memory array of FIG. 2 when a first type of logical value is stored in the data storage element and a “match” condition happens.

FIG. 6 is a diagram illustrating the search operation of the TCAM mode of the memory array of FIG. 2 when the first type of logical value is stored in the data storage element and a “mismatch” condition happens.

FIG. 7 is a diagram illustrating the search operation of the TCAM mode of the memory array of FIG. 2 when a second type of logical value is stored in the data storage element and a “mismatch” condition happens.

FIG. 8 is a diagram illustrating the search operation of the TCAM mode of the memory array of FIG. 2 when the second type of logical value is stored in the data storage element and a “match” condition happens.

FIG. 9 is a diagram illustrating the search operation of the TCAM mode of the memory array of FIG. 2 when a third type of logical value is stored in the data storage element and a “match” condition happens.

FIG. 10 is a diagram illustrating the search operation of the TCAM mode of the memory array of FIG. 2 when the third type of logical value is stored in the data storage element and a “match” condition happens.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The terms “couple,” “coupled” and “coupling” used throughout the present disclosure describe the direct or indirect connections between two or more devices or elements. In some cases, a coupling between at least two devices or elements refers to mere electrical or conductive connections between them and intervening features may be present between the coupled devices and elements. In some other cases, a coupling between at least two devices or elements may involve physical contact and/or electrical connections.

The terms “activate,” “activating” and “activated” used throughout the present disclosure describe an operation of enabling a device or component, such as a transistor. The activation may involve application of a biasing voltage on a transistor (e.g., on the gate terminal of the transistor) to operate the transistor in a conductive state (also referred to as an active state herein), such as in a saturation region or a triode region, so that the transistor functions as being “turned on” like a switch that has been turned on. In some cases, a period of time is required for the transistor to attain the conductive state.

The terms “deactivate,” “deactivating” and “deactivated” used throughout the present disclosure describe an operation of disconnecting a device or component within a device from external conductive features. The deactivation may involve application of a biasing voltage on a transistor (e.g., on the gate terminal of the transistor) to operate the transistor in a non-conductive or disconnected state (also referred to as an inactive state herein), such as in a cut-off region, so that the transistor functions as being “turned off” like a switch that has been turned off. In some cases, a period of time is required for the transistor to attain the non-conductive state. In some embodiments, however, whereas a deactivating operation cuts off the electrical connection between the device and external features, the device or component may still maintain power at internal nodes for specific purposes. Thus, an operation of deactivating does not necessarily guarantee a complete halt of power consumption.

As used herein, the terms “approximate,” “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation.

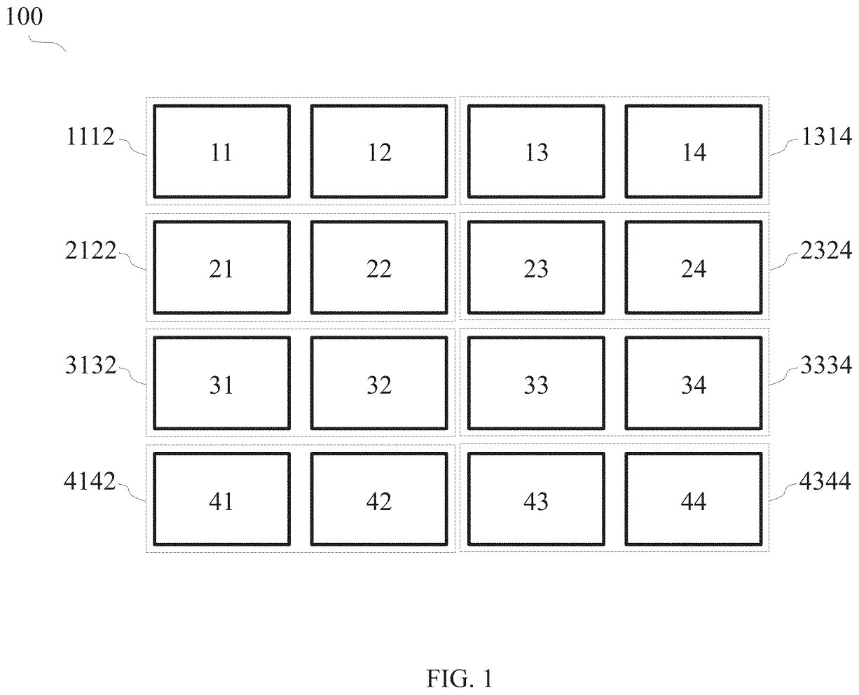

FIG. 1 is a diagram illustrating a memory array 100, in accordance with some embodiments of the present disclosure. The memory array 100 is formed of a plurality of memory cells arranged in columns and rows, in which 16 memory cells are shown for illustrative purpose, i.e., memory cells 11-14, memory cells 21-24, memory cells 31-34, and memory cells 41-44. The memory cells of the memory array 100 have the same structure. Please note that bit lines, word lines, and peripheral elements such as sense amplifiers are not shown in FIG. 1 for brevity but are covered in the following drawings and associated paragraphs.

The memory array 100 is capable of operating in three different modes including a dual-port SRAM mode, a BCAM mode, and a TCAM mode. When the memory array 100 operates in the dual-port SRAM mode, each of the 16 memory cells in FIG. 1 is used as a dual-port SRAM unit cell. When the memory array 100 operates in the BCAM mode, each of the 16 memory cells in FIG. 1 is used as a BCAM unit cell.

By contrast, when the memory array 100 operates in the TCAM mode, the 16 memory cells in FIG. 1 form 8 TCAM unit cell units in a two-to-one relationship. In particular, the memory cell 11 and the memory cell 12 form a TCAM unit cell 1112; the memory cell 13 and the memory cell 14 form a TCAM unit cell 1314; the memory cell 21 and the memory cell 22 form a TCAM unit cell 2122; the memory cell 23 and the memory cell 24 form a TCAM unit cell 2324; the memory cell 31 and the memory cell 32 form a TCAM unit cell 3132; the memory cell 33 and the memory cell 34 form a TCAM unit cell 3334; the memory cell 41 and the memory cell 42 form a TCAM unit cell 4142; the memory cell 43 and the memory cell 44 form a TCAM unit cell 4344.

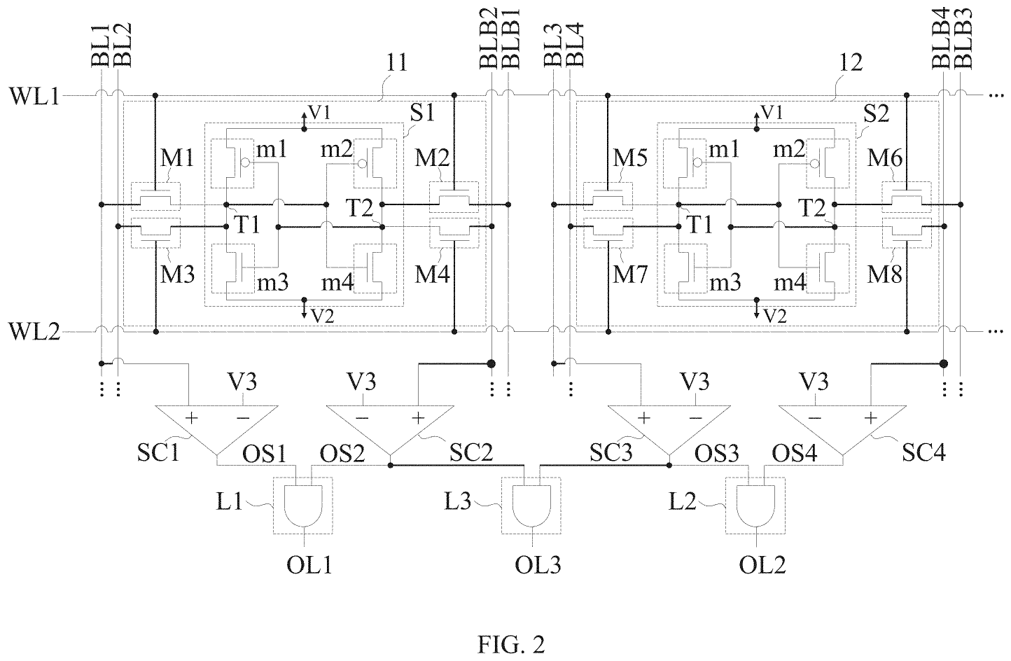

FIG. 2 is a schematic circuit diagram illustrating the memory array, in accordance with an embodiment of the present disclosure. FIG. 2 shows only a portion of the memory array 100 but with further details. As can be seen in FIG. 2, the memory cell 11 and the memory cell 12 are both a typical 8-T dual-port SRAM cell. Specifically, the memory cell 11 and the memory cell 12 are in the same row and in different columns of the memory array 100. The memory cell 11 includes a data storage element S1. The data storage element S1 is formed of two inverters each including a load transistor m1 (or m2) and a drive transistor m3 (or m4). The load transistors m1 and m2, constructed by P-channel transistors, are coupled to a first reference voltage V1. The drive transistors m3 and m4, constructed by N-channel transistors, are coupled to a second reference voltage V2. In the present embodiment, the first reference voltage V1 is higher than the second reference voltage V2. The two inverters are cross coupled to each other to constitute a latch such that voltages at a first terminal (i.e., a data node) T1 and a second terminal (i.e., a complementary data node) T2 form a pair of complementary logic values (i.e., a pair of ‘1’ and ‘0’, or a pair of ‘0’ and ‘1’) representing a data bit. Please note that in this disclosure, the first terminal T1 and the second terminal T2 being respectively logical high (“1”) and logical low (“0”) stands for a data bit of logical high (“1”), and the first terminal T1 and the second terminal T2 being respectively logical low (“0”) and logical high (“1”) stands for a data bit of logical low (“0”) in the memory cell.

The memory cell 11 can be accessed by two independent sets of control lines. The first set of control lines includes a bit line BL1, a complementary bit line BLB1, and a word line WL1. The second set of control lines includes a bit line BL2, a complementary bit line BLB2, and a word line WL2. The bit line BL1 is coupled to a first port of the memory cell 11. The complementary bit line BLB1 is coupled to a first complementary port of the memory cell 11. The bit line BL2 is coupled to a second port of the memory cell 11. The complementary bit line BLB2 is coupled to a second complementary port of the memory cell 11.

An access transistor M1 is coupled between the bit line BL1 and the first terminal T1 of the data storage element S1. An access transistor M2 is coupled between the complementary bit line BLB1 and the second terminal T2 of the data storage element S1. An access transistor M3 is coupled between the bit line BL2 and the first terminal T1 of the data storage element S1. An access transistor M4 is coupled between the complementary bit line BLB2 and the second terminal T2 of the data storage element S1. The word line WL1 is configured to selectively enable the access to the data storage element S1 through the access transistor M1 and the access transistor M2. The word line WL2 is configured to selectively enable the access to the data storage element S1 through the access transistor M3 and the access transistor M4.

When the memory array 100 operates in the dual-port SRAM mode and performs a write operation, the word line WL1 is asserted to activate the access transistor M1 and the access transistor M2, thus enabling data transfer from the bit line BL1 and the complementary bit line BLB1 to the data storage element S1; alternatively, the word line WL2 is asserted to activate the access transistor M3 and the access transistor M4, thus enabling data transfer from the bit line BL2 and the complementary bit line BLB2 to the data storage element S1.

When the memory array 100 operates in the dual-port SRAM mode and performs a read operation, the bit lines BL1-BL2 and the complementary bit lines BLB1-BLB2 start to get pre-charged to logical high (“1”). After the pre-charge, the word line WL1 is asserted to activate the access transistor M1 and the access transistor M2, enabling data transfer from the data storage element S1 to the bit line BL1 and the complementary bit line BLB1; alternatively, the word line WL2 is asserted to activate the access transistor M3 and the access transistor M4, thus enabling data transfer from the data storage element S1 to the bit line BL2 and the complementary bit line BLB2.

In the present embodiment, a comparator SC1 is arranged for generating a sensed result OS1 according to a logic level of the bit line BL1 and a reference voltage V3, and a comparator SC2 is arranged for generating a sensed result OS2 according to a logic level of the complementary bit line BLB2 and the reference voltage V3. The comparators SC1 and SC2 may be constructed by transistors. As shown in FIG. 2, each of the comparators SC1 and SC2 is configured to sense voltage differences between a non-inverting input (+) and an inverting input (−). The comparator SC1 or SC2 may be implemented as voltage mode, current mode, charge transfer mode, or the like. In the present embodiment, the comparators SC1 and SC2 are single-ended sense amplifiers.

Please note that the voltage level of the reference voltage V3 is lower than the voltage level of logical high (“1”) and higher than the voltage level of logical low (“0”). If the logic value of the data bit at the first terminal T1 of the data storage element S1 is logical high (“1”), when the data bit is read out from the data storage element S1 via the access transistor M1 to the bit line BL1, the bit line BL1 stays at logical high (“1”) with a voltage level higher than the reference voltage V3. As a result, the sensed result OS1 becomes logical high (“1”). On the contrary, if the logic value of the data bit at the first terminal T1 of the data storage element S1 is logical low (“0”), when the data bit is read out from the data storage element S1 via the access transistor M1 to the bit line BL1, the bit line BL1 goes down to logical low (“0”) with a voltage level lower than the reference voltage V3. As a result, the sensed result OS1 becomes logical low (“0”).

Similarly, if the complementary logic value of the data bit at the second terminal T2 of the data storage element S1 is logical high (“1”), when the data bit is read out from the data storage element S1 via the access transistor M4 to the complementary bit line BLB2, the complementary bit line BLB2 stays at logical high (“1”) with a voltage level higher than the reference voltage V3. As a result, the sensed result OS2 becomes logical high (“1”). On the contrary, if the complementary logic value of the data bit at the second terminal T2 of the data storage element S1 is logical low (“0”), when the data bit is read out from the data storage element S1 via the access transistor M4 to the complementary bit line BLB2, the complementary bit line BLB2 goes down to logical low (“0”) with a voltage level lower than the reference voltage V3. As a result, the sensed result OS2 becomes logical low (“0”).

A mentioned above, the structure of the memory cell 12 and the memory cell 11 are substantially the same. The memory cell 12 includes a data storage element S2. The memory cell 12 can be accessed by two independent sets of control lines. The first set of control lines includes a bit line BL3, a complementary bit line BLB3, and the word line WL1. The second set of control lines includes a bit line BL4, a complementary bit line BLB4, and the word line WL2. An access transistor M5 is coupled between the bit line BL3 and a first terminal T1 of the data storage element S2. An access transistor M6 is coupled between the complementary bit line BLB3 and a second terminal T2 of the data storage element S2. An access transistor M7 is coupled between the bit line BL4 and the first terminal T1 of the data storage element S2. An access transistor M8 is coupled between the complementary bit line BLB4 and the second terminal T2 of the data storage element S2. The word line WL1 is configured to selectively enable the access to the data storage element S2 through the access transistor M5 and the access transistor M6. The word line WL2 is configured to selectively enable the access to the data storage element S2 through the access transistor M7 and the access transistor M8. A comparator SC3 is arranged for generating a sensed result OS3 according to a logic level of the bit line BL3 and the reference voltage V3; a comparator SC4 is arranged for generating a sensed result OS4 according to a logic level of the complementary bit line BLB4 and the reference voltage V3. The comparators SC3 and SC4 may be constructed by transistors. Each of the comparators SC3 and SC4 is configured to sense voltage differences between a non-inverting input (+) and an inverting input (−). The comparator SC3 or SC4 may be implemented as voltage mode, current mode, charge transfer mode, or the like. In the present embodiment, the comparators SC3 or SC4 are single-ended sense amplifiers.

The above description relates to the operation of the dual-port SRAM mode of the memory array 100. Logic circuits L1, L2 and L3 are not discussed yet because logic circuits L1 and L2 are for use in the BCAM mode and the TCAM mode. The logic circuit L3 is only for use in the TCAM mode. The operations of the memory array 100 under the BCAM mode and the TCAM mode are provided in the following paragraphs.

As discussed above, when the memory array 100 operates in the dual-port SRAM mode, each memory cell independently stores a data bit. It also applies to the BCAM mode. When the memory array 100 operates in the BCAM mode, the effective capacity is the same as the effective capacity in the dual-port SRAM mode. But when the memory array 100 operates in the TCAM mode, the effective capacity is half the effective capacity of the dual-port SRAM mode.

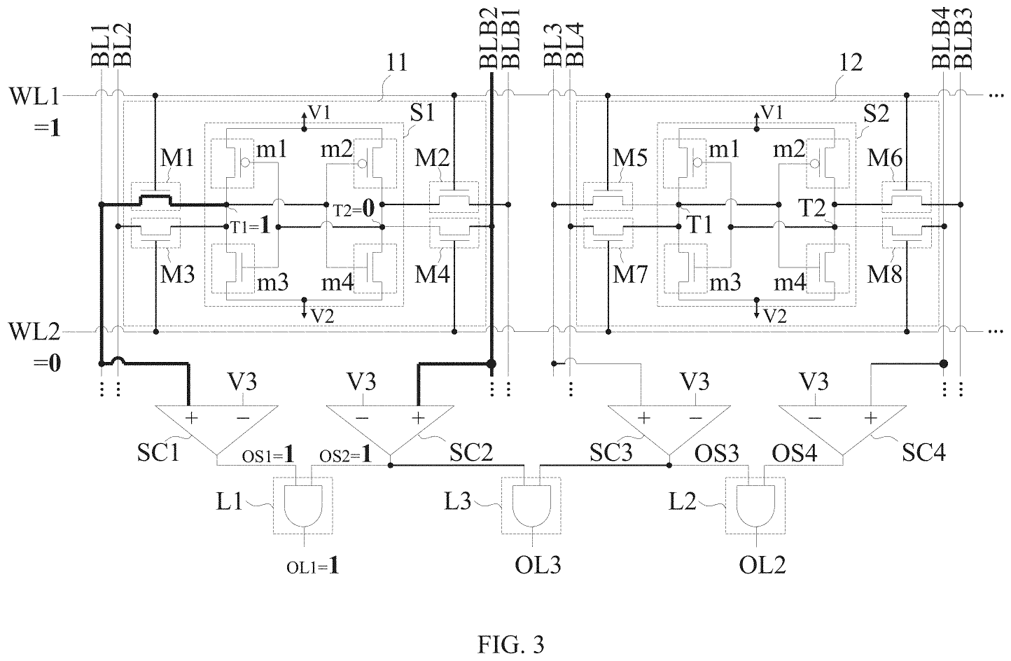

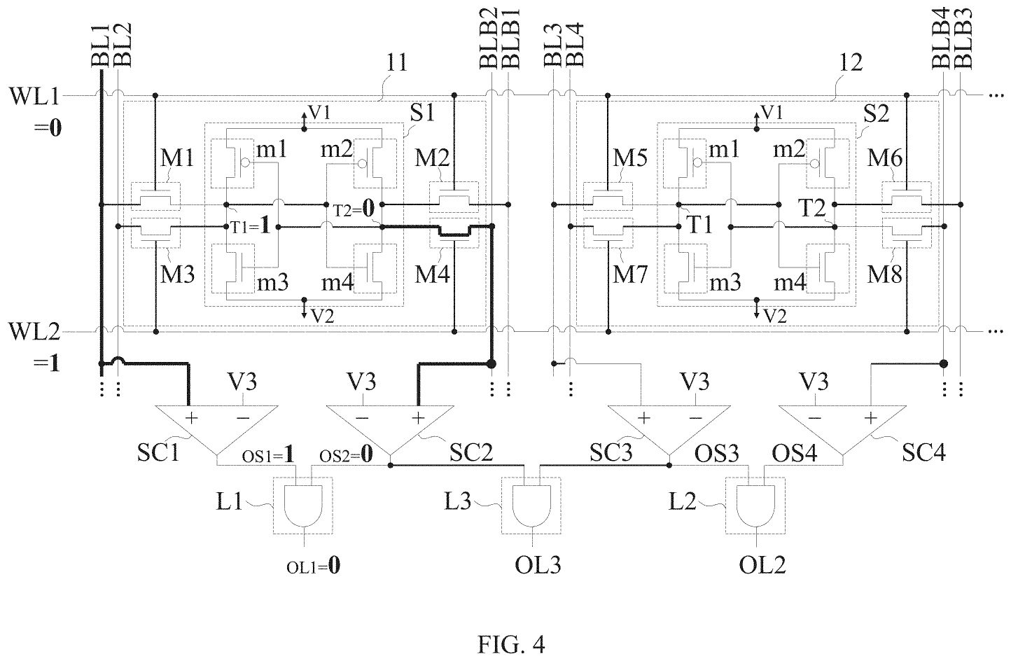

FIG. 3 is a diagram illustrating the search operation of the BCAM mode of the memory array of FIG. 2 when a “match” condition happens. FIG. 4 is a diagram illustrating the search operation of the BCAM mode of the memory array of FIG. 2 when a “mismatch” condition happens. In short, when the memory array 100 operates in the BCAM mode and performs a search operation, a logic output OL1 generated from the logic circuit L1 indicates whether two conditions are both met. One condition is that a logic level of the word line WL1 matches the logic value at the first terminal T1 of the data storage element S1. The other condition is that a logic level of the word line WL2 matches the complementary logic value at the second terminal T2 of the data storage element S1. In the present embodiment, the logic circuit L1 is implemented by an AND gate. However, this is not a limitation of the present disclosure. In some embodiment, other combinational circuit may be employed. For instance, a NAND gate may be used to replace the AND gate.

In the BCAM mode, each of the memory cells of the memory array 100 can be configured to have a data bit by the write operation. When the search operation begins, the bit lines BL1, BL2, and the complementary bit lines BLB1, BLB2 start to get pre-charged to logical high (“1”) in a way the same as the read operation in the dual-port SRAM mode. After the pre-charge, the word lines WL1 and WL2 are configured as search lines. For clarity, a portion of FIG. 3 is highlighted by the bold text and bold lines. As shown, data storage element S1 is in a condition that the logic value at the first terminal T1 and the complementary logic value at the second terminal T2 are logical high (“1”) and logical low (“0”) respectively. When the word line WL1 is logical high (“1”) and the word line WL2 is logical low (“0”), the access transistor M1 is activated and the access transistor M4 is deactivated. Since the logic value at the first terminal T1 is logical high (“1”), the logical value of the bit line BL1 remains logical high (“1”) after the access transistor M1 is activated. On the other hand, the access transistor M4 is deactivated so the logical low (“0”) of the second terminal T2 does not pulls down the complementary bit line BLB2. The logical value of the complementary bit line BLB2 remains logical high (“1”) accordingly. The sensed results OS1 and OS2 are both logical high (“1”) in FIG. 3's condition. As a result, the logic output OL1 is logical high (“1”) which indicates a “match” condition happens.

Please refer to FIG. 4, the data storage element S1 has the same condition as illustrated in FIG. 3, but the search condition changes. Similarly, a portion of FIG. 4 is highlighted by the bold text and bold lines. As can be seen in FIG. 4, the word line WL1 is logical high (“0”) and the word line WL2 is logical low (“1”). Thus, the access transistor M1 is deactivated and the access transistor M4 is activated. The logical value of the bit line BL1 remains logical high (“1”) since the access transistor M1 is deactivated. On the other hand, the logic value at the second terminal T2 is logical low (“0”) which can pull down the complementary bit line BLB2 to logical low (“0”) as well after the access transistor M4 is activated. So, the sensed results OS1 and OS2 are logical high (“1”) and logical low (“0”) respectively in FIG. 4's condition. As a result, the logic output OL1 is logical low (“0”) which indicates a “mismatch” condition happens.

In light of the above, when the logical values of the word lines WL1 and WL2 respectively matches the logical values of the first and the second terminals T1-T2 of the data storage element S1, a “match” condition happens, or else a “mismatch” condition happens.

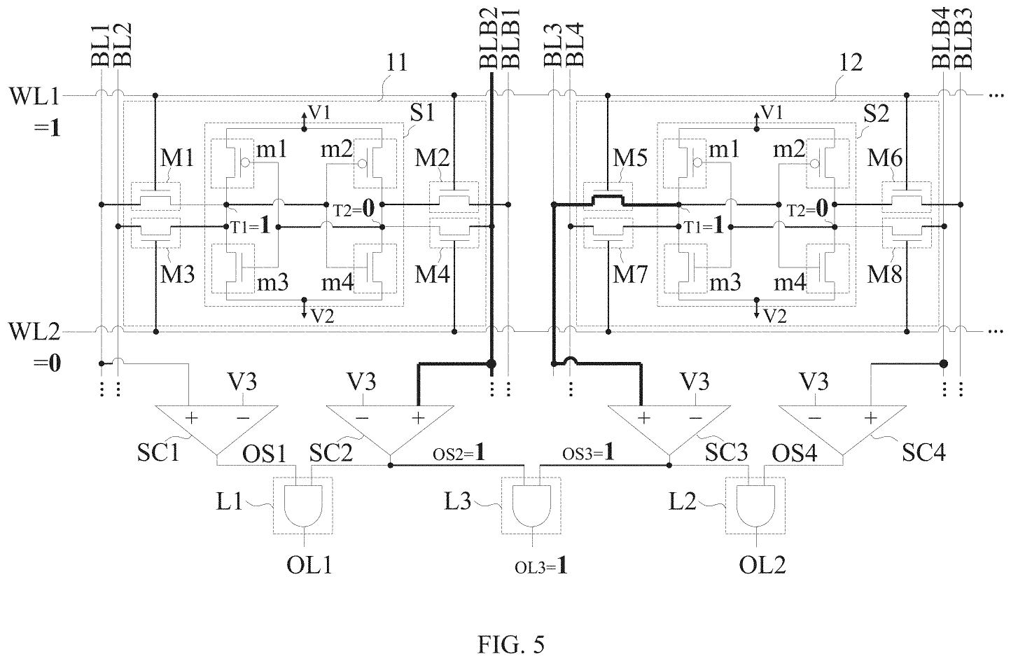

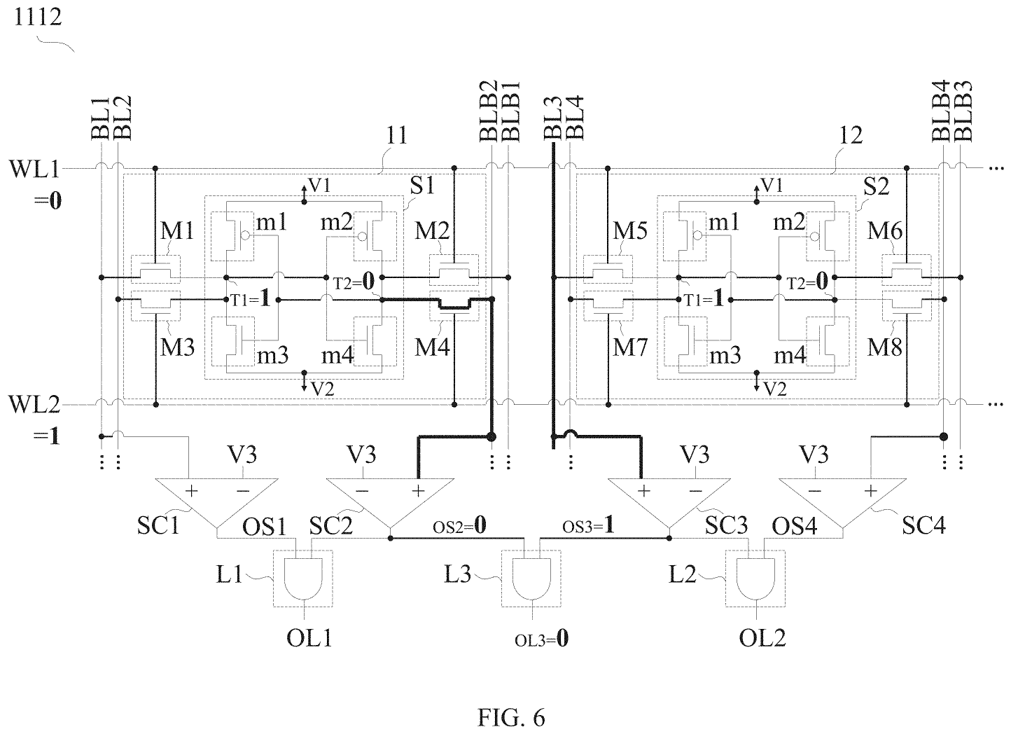

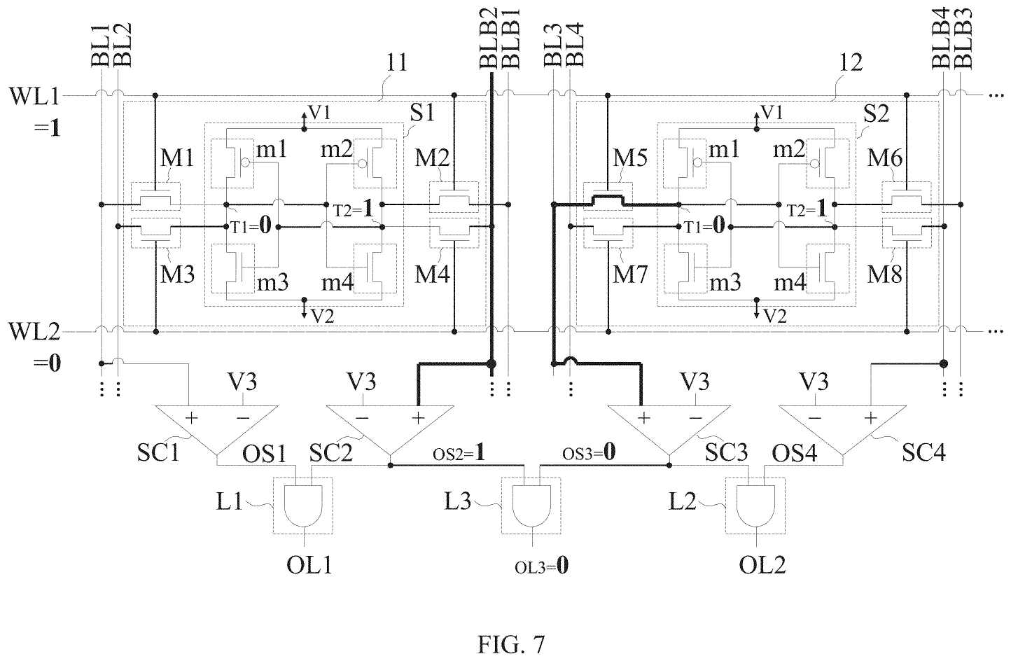

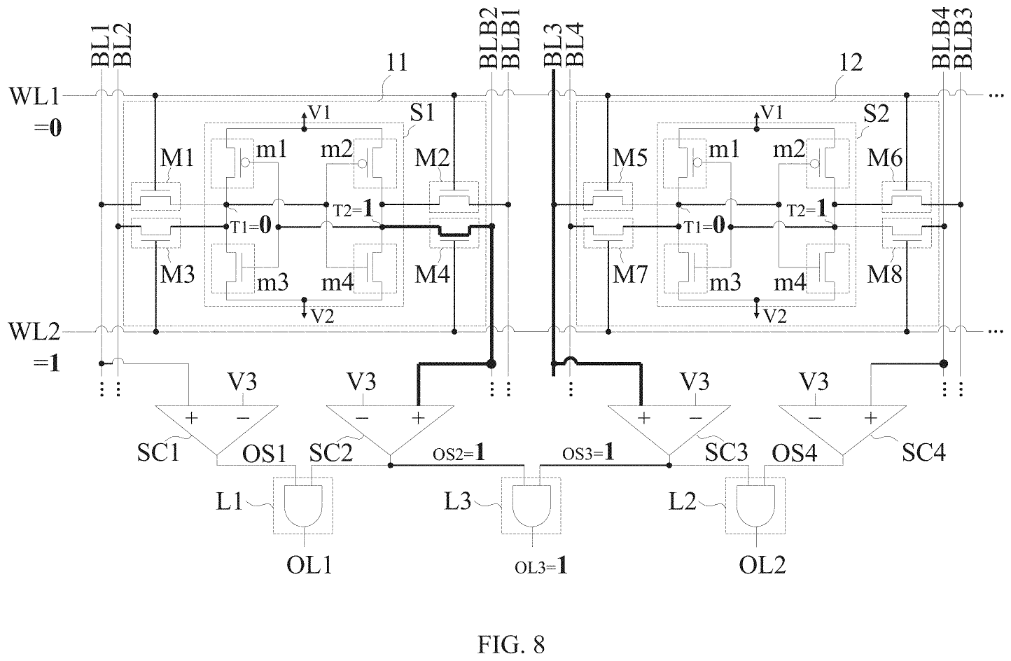

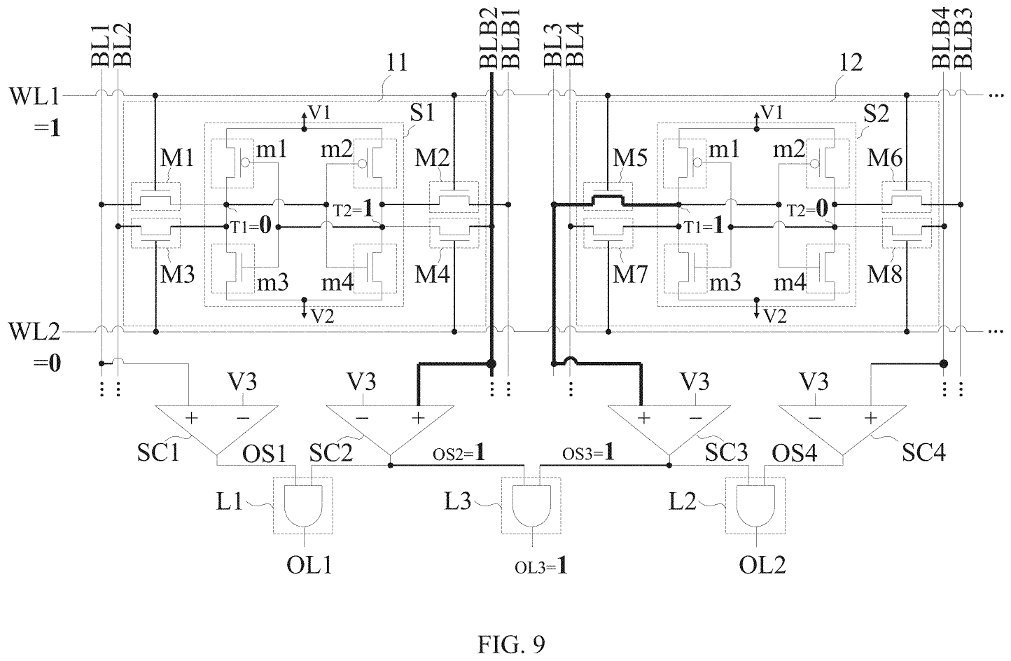

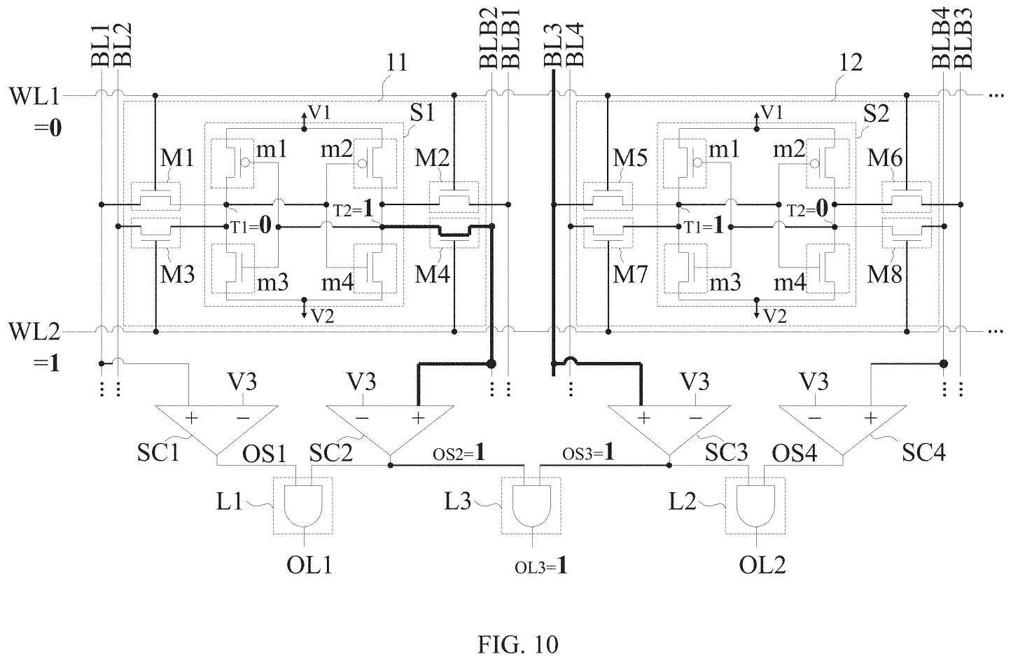

FIG. 5 is a diagram illustrating the search operation of the TCAM mode of the memory array of FIG. 2 when a first type of logical value is stored in the data storage element and a “match” condition happens. FIG. 6 is a diagram illustrating the search operation of the TCAM mode of the memory array of FIG. 2 when the first type of logical value is stored in the data storage element and a “mismatch” condition happens. FIG. 7 is a diagram illustrating the search operation of the TCAM mode of the memory array of FIG. 2 when a second type of logical value is stored in the data storage element and a “mismatch” condition happens. FIG. 8 is a diagram illustrating the search operation of the TCAM mode of the memory array of FIG. 2 when the second type of logical value is stored in the data storage element and a “match” condition happens. FIG. 9 is a diagram illustrating the search operation of the TCAM mode of the memory array of FIG. 2 when a third type of logical value is stored in the data storage element and a “match” condition happens. FIG. 10 is a diagram illustrating the search operation of the TCAM mode of the memory array of FIG. 2 when the third type of logical value is stored in the data storage element and a “match” condition happens.

In short, when the memory array 100 operates in the TCAM mode and performs a search operation, a logic output OL3 generated from the logic circuit L3 indicates whether two conditions are both met. One condition is that a logic level of the word line WL2 matches the complementary logic value at the second terminal T2 of the data storage element S1. The other condition is that a logic level of the word line WL1 matches the logic value at the first terminal T1 of the data storage element S2. In the present embodiment, the logic circuit L3 is implemented by an AND gate. However, this is not a limitation of the present disclosure. In some embodiment, other combinational circuit may be employed. For instance, a NAND gate may be used to replace the AND gate.

In the TCAM mode, each of the memory cells of the memory array 100 can be configured to have a data bit by the write operation. But the memory cells have to be configured to operate in pairs. For example, the memory cell 11 and the memory cell 12 together form the TCAM unit cell 1112, and the storage conditions of the data storage elements S1-S2 are jointly considered to represent a logical value. In specific, both of the data bits of the data storage elements S1 and S2 being logical high (“1”) represents that the TCAM unit cell 1112 as a whole has a logical value which is logical high (“1”); both of the data bits of the data storage elements S1 and S2 being logical low (“0”) represents that the TCAM unit cell 1112 as a whole has a logical value which is logical low (“0”); the data bit of the data storage elements S1 being logical low (“0”) and the data bit of the data storage elements S2 being logical high (“1”) represents that the TCAM unit cell 1112 as a whole has a logical value which is “don't care”.

In the TCAM mode, when the search operation begins, the bit lines BL1-BL4 and the complementary bit lines BLB1-BLB4 start to get pre-charged to logical high (“1”) in a way the same as the read operation in the dual-port SRAM mode. After the pre-charge, the word lines WL1 and WL2 are configured as search lines. As indicated in FIG. 5 by the bold text and bold lines, the data storage element S1 is in a condition that the logic value at the first terminal T1 and the complementary logic value at the second terminal T2 are logical high (“1”) and logical low (“0”) respectively. The data storage element S2 has exactly the same condition as that of the data storage element S1. As mentioned above, the TCAM unit cell 1112 as a whole stores a logical value which is logical high (“1”) in this case.

When the word line WL1 is logical high (“1”) and the word line WL2 is logical low (“0”), the access transistor M4 is deactivated and the access transistor M5 is activated. The access transistor M4 is deactivated so the logical low (“0”) of the second terminal T2 of the data storage element S1 does not pulls down the complementary bit line BLB2. The logical value of the complementary bit line BLB2 remains logical high (“1”) accordingly. On the other hand, since the logic value at the first terminal T1 of the data storage element S2 is logical high (“1”), the logical value of the bit line BL3 remains logical high (“1”) after the access transistor M5 is activated. The sensed results OS2 and OS3 are both logical high (“1”) in FIG. 5's condition. As a result, the logic output OL3 is logical high (“1”) which indicates a “match” condition happens.

Please refer to FIG. 6, the data storage elements S1 and S2 have the same condition as illustrated in FIG. 5, but the search condition changes. A portion of FIG. 6 is highlighted by the bold text and bold lines to make the following description easy to understand. As can be seen, the word line WL1 is logical low (“0”) and the word line WL2 is logical high (“1”). Thus the access transistor M4 is activated and the access transistor M5 is deactivated. The logic value at the second terminal T2 of the data storage element S1 is logical low (“0”) which can pull down the complementary bit line BLB2 to logical low (“0”) as well after the access transistor M4 is activated. On the other hand, the logical value of the bit line BL3 remains logical high (“1”) since the access transistor M1 is deactivated. So, the sensed results OS2 and OS3 are logical low (“0”) and logical high (“1”) respectively in FIG. 6's condition. As a result, the logic output OL3 is logical low (“0”) which indicates a “mismatch” condition happens.

In light of the above, when both of the data bits of the data storage elements S1 and S2 are logical high (“1”), i.e., the TCAM unit cell 1112 as a whole has a logical value which is logical high (“1”), a “match” condition only happens if the logical values of the word lines WL1 and WL2 are logical high (“1”) and logical low (“0) respectively.

As indicated in FIG. 7 by the bold text and bold lines, the data storage element S1 is in a condition that the logic value at the first terminal T1 and the complementary logic value at the second terminal T2 are logical low (“0”) and logical high (“1”) respectively. The data storage element S2 has exactly the same condition as that of the data storage element S1. As mentioned above, the TCAM unit cell 1112 as a whole stores a logical value which is logical low (“0”) in this case.

When the word line WL1 is logical high (“1”) and the word line WL2 is logical low (“0”), the access transistor M4 is deactivated and the access transistor M5 is activated. The logical value of the complementary bit line BLB2 remains logical high (“1”) because the access transistor M4 is deactivated. On the other hand, the logical value at the first terminal T1 of the data storage element S2 is logic low (“0”) which can pull the bit line BL3 because the access transistor M5 is activated. The sensed results OS2 and OS3 are logical high (“1”) and logical low (“0”) respectively in FIG. 7's condition. As a result, the logic output OL3 is logical low (“0”) which indicates a “mismatch” condition happens.

Please refer to FIG. 8, the data storage elements S1 and S2 have the same condition as illustrated in FIG. 7, but the search condition changes. A portion of FIG. 6 is highlighted by the bold text and bold lines to make the following description easy to understand. As show, the word line WL1 is logical low (“0”) and the word line WL2 is logical high (“1”). Thus the access transistor M4 is activated and the access transistor M5 is deactivated. Because the logic value at the second terminal T2 of the data storage element S1 is logical high (“1”), the logical value of the complementary bit line BLB2 remains logical high (“1”) after the access transistor M4 is activated. On the other hand, the logical value of the bit line BL3 remains logical high (“1”) since the access transistor M5 is deactivated. So, the sensed results OS2 and OS3 are both logical high (“1”) in FIG. 8's condition. As a result, the logic output OL3 is logical low (“1”) which indicates a “match” condition happens.

In light of the above, when both of the data bits of the data storage elements S1 and S2 are logical low (“0”), i.e., the TCAM unit cell 1112 as a whole has a logical value which is logical low (“0”), a “match” condition only happens if the logical values of the word lines WL1 and WL2 are logical low (“0”) and logical high (“1”) respectively.

As indicated in FIG. 9 by the bold text and bold lines, the data storage element S1 is in a condition that the logic value at the first terminal T1 and the complementary logic value at the second terminal T2 are logical low (“0”) and logical high (“1”) respectively. The storage condition of the data storage element S2 is exactly opposite to that of the data storage element S1. As mentioned above, the TCAM unit cell 1112 as a whole stores a logical value which is “don't care” in this case.

When the word line WL1 is logical high (“1”) and the word line WL2 is logical low (“0”), the access transistor M4 is deactivated and the access transistor M5 is activated. The logical value of the complementary bit line BLB2 remains logical high (“1”) because the access transistor M4 is deactivated. On the other hand, since the first terminal T1 of the data storage element S2 is the logical high (“1”), the logical value of the bit line BL3 remains logical high (“1”) when the access transistor M5 is activated. The sensed results OS2 and OS3 are both logical high (“1”) in FIG. 9's condition. As a result, the logic output OL3 is logical high (“1”) which indicates a “match” condition happens.

Please refer to FIG. 10, the data storage elements S1 and S2 are the same condition as illustrated in FIG. 9, but the search condition changes. In FIG. 10, the word line WL1 is logical low (“0”) and the word line WL2 is logical high (“1”). Thus the access transistor M4 is activated and the access transistor M5 is deactivated. Because the logic value at the second terminal T2 of the data storage element S1 is logical high (“1”), the logical value of the complementary bit line BLB2 remains logical high (“1”) after the access transistor M4 is activated. On the other hand, the logical value of the bit line BL3 remains logical high (“1”) since the access transistor M5 is deactivated. So, the sensed results OS2 and OS3 are both logical high (“1”) in FIG. 10's condition. As a result, the logic output OL3 is logical high (“1”) which indicates a “match” condition happens.

In light of the above, when the data bit of the data storage elements S1 is logical low (“0”) and the data bit of the data storage elements S2 is logical high (“1”) respectively, i.e., the TCAM unit cell 1112 as a whole has a logical value which is “don't care”, a “match” condition happens if the logical values of the word lines WL1 and WL2 are logical low (“0”) and logical high (“1”) respectively, and vice versa.

The memory array 100 of the present disclosure is reconfigurable to switch among the SRAM, BCAM and TCAM modes, and has twice the capacity in the SRAM and BCAM modes than in the TCAM mode. In this way, the flexibility and capacity utilization of the memory array 100 is much higher than that of existing memory arrays. In some embodiments, the memory array 100 may be included in a semiconductor chip.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory array, comprising:
a plurality of first dual-port static random access memory (SRAM) cells, each having a first port, a first complementary port, a second port, and a second complementary port;
a first bit line, coupled to the first port of each of the first dual-port SRAM cells;
a first complementary bit line, coupled to the first complementary port of each of the first dual-port SRAM cells;
a second bit line, coupled to the second port of each of the first dual-port SRAM cells;
a second complementary bit line, coupled to the second complementary port of each of the first dual-port SRAM cells;
a first comparator, having a first input and a second input, wherein the first input of the first comparator is coupled to the first bit line, and the second input of the first comparator is coupled to a reference voltage;
a second comparator, having a first input and a second input, wherein the first input of the second comparator is coupled to the second complementary bit line, and the second input of the second comparator is coupled to the reference voltage; and
a first logic circuit, arranged for generating a first logic output according to an output of the first comparator and an output of the second comparator.

2. The memory array according to claim 1, further comprising:
a plurality of second dual-port SRAM cells, each having a first port, a first complementary port, a second port, and a second complementary port;
a third bit line, coupled to the first port of each of the second dual-port SRAM cells;
a third complementary bit line, coupled to the first complementary port of each of the second dual-port SRAM cells;
a fourth bit line, coupled to the second port of each of the second dual-port SRAM cells;
a fourth complementary bit line, coupled to the second complementary port of each of the second dual-port SRAM cells;
a third comparator, having a first input and a second input, wherein the first input of the third comparator is coupled to the third bit line, and the second input of the third comparator is coupled to the reference voltage;
a fourth comparator, having a first input and a second input, wherein the first input of the fourth comparator is coupled to the fourth complementary bit line, and the second input of the fourth comparator is coupled to the reference voltage;
a second logic circuit, arranged for generating a second logic output according to an output of the third comparator and an output of the fourth comparator; and
a third logic circuit, arranged for generating a third logic output according to the output of the second comparator and the output of the third comparator.

3. The memory array according to claim 2, wherein each of the first logic circuit, the second logic circuit, and the third logic circuit includes an AND gate.

4. A memory array, comprising:
a first dual-port static random access memory (SRAM) cell, having a first port, a first complementary port, a second port, and a second complementary port;
a second dual-port SRAM cell, having a first port, a first complementary port, a second port, and a second complementary port;
a first bit line, coupled to the first port of the first dual-port SRAM cell;
a second complementary bit line, coupled to the second complementary port of the first dual-port SRAM cell;
a third bit line, coupled to the first port of the second dual-port SRAM cell;
a fourth complementary bit line, coupled to the second complementary port of the second dual-port SRAM cell;
a first comparator, for comparing a voltage level of the first bit line and a voltage level of a reference voltage;
a second comparator, for comparing a voltage level of the second complementary bit line and the voltage level of the reference voltage;
a third comparator, for comparing a voltage level of the third bit line and the voltage level of the reference voltage;
a fourth comparator, for comparing a voltage level of the fourth complementary bit line and the voltage level of the reference voltage;
a first logic gate, arranged for generating a first logic output according to an output of the first comparator and an output of the second comparator;
a second logic gate, arranged for generating a second logic output according to an output of the third comparator and an output of the fourth comparator; and
a third logic gate, arranged for generating a third logic output according to the output of the second comparator and the output of the third comparator.

5. The memory array according to claim 4, further comprising:
a first word line, configured to:
selectively enable access to the first dual-port SRAM cell through the first port and the first complementary port of the first dual-port SRAM cell; and
selectively enable access to the second dual-port SRAM cell through the first port and the first complementary port of the second dual-port SRAM cell; and
a second word line, configured to:
selectively enable access to the first dual-port SRAM cell through the second port and the second complementary port of the first dual-port SRAM cell; and
selectively enable access to the second dual-port SRAM cell through the second port and the second complementary port of the second dual-port SRAM cell.

6. A memory array, comprising:
a first memory cell, including:
a first data storage element having a first terminal and a second terminal, wherein the first data storage element stores a first logic value at the first terminal and a first complementary logic value at the second terminal;
a first access transistor coupled to the first terminal of the first data storage element;
a second access transistor coupled to the second terminal of the first data storage element;
a third access transistor coupled to the first terminal of the first data storage element; and
a fourth access transistor coupled to the second terminal of the first data storage element;
a first word line, configured to selectively enable access to the first data storage element through the first access transistor and the second access transistor;
a second word line, configured to selectively enable access to the first data storage element through the third access transistor and the fourth access transistor;
a first bit line, wherein the first access transistor is coupled between the first bit line and the first terminal of the first data storage element;
a first complementary bit line, wherein the second access transistor is coupled between the first complementary bit line and the second terminal of the first data storage element;
a second bit line, wherein the third access transistor is coupled between the second bit line and the first terminal of the first data storage element;
a second complementary bit line, wherein the fourth access transistor is coupled between the second complementary bit line and the second terminal of the first data storage element;
a first sense amplifier, arranged for generating a first sensed result according to a logic level of the first bit line and a reference voltage;
a second sense amplifier, arranged for generating a second sensed result according to a logic level of the second complementary bit line and the reference voltage; and
a first logic circuit, arranged for generating a first logic output according to the first sensed result and the second sensed result;
wherein:
when the memory array operates in a dual-port static random access memory (SRAM) mode, the first sensed result indicates the first logic value stored at the first terminal of the first data storage element, in response to selection of the first word line during a read operation, and the second sensed result indicates the first complementary logic value stored at the second terminal of the first data storage element, in response to selection of the second word line during the read operation;
when the memory array operates in a binary content-addressable memory (BCAM) mode and performs a search operation, the first logic output indicates whether a logic level of the first word line matches the first logic value, and whether a logic level of the second word line matches the first complementary logic value; and
a voltage level of the reference voltage is lower than logical high and higher than logical low.

7. The memory array according to claim 6, wherein when the memory array operates in the BCAM mode and performs the search operation, the first bit line and the second complementary bit line are pre-charged to a high logic level at first.

8. The memory array according to claim 7, wherein when the memory array operates in the BCAM mode, during the search operation, if the first logic value, the first complementary logic value, the first word line, and the second word line are logical high, logical low, logical high, and logical low respectively, then a voltage level of the first sensed result and a voltage level of the second sensed result are both logical high.

9. The memory array according to claim 7, wherein when the memory array operates in the BCAM mode, during the search operation, if the first logic value, the first complementary logic value, the first word line, and the second word line are logical high, logical low, logical low, and logical high respectively, then a voltage level of the first sensed result is logical high and a voltage level of the second sensed result is logical low.

10. The memory array according to claim 6, further comprising:
a second memory cell, including:
a second data storage element having a first terminal and a second terminal, wherein the second data storage element stores a second logic value at the first terminal and a second complementary logic value at the second terminal;
a fifth access transistor coupled to the first terminal of the second data storage element;
a sixth access transistor coupled to the second terminal of the second data storage element, wherein the first word line is further configured to selectively enable access to the second data storage element through the fifth access transistor and the sixth access transistor;
a seventh access transistor coupled to the first terminal of the second data storage element; and
an eighth access transistor coupled to the second terminal of the second data storage element, wherein the second word line is further configured to selectively enable access to the second data storage element through the seventh access transistor and the eighth access transistor;
a third bit line, wherein the fifth access transistor is coupled between the third bit line and the first terminal of the second data storage element;
a third complementary bit line, wherein the sixth access transistor is coupled between the third complementary bit line and the second terminal of the second data storage element;
a fourth bit line, wherein the seventh access transistor is coupled between the fourth bit line and the first terminal of the second data storage element;
a fourth complementary bit line, wherein the eighth access transistor is coupled between the fourth complementary bit line and the second terminal of the second data storage element;
a third sense amplifier, arranged for generating a third sensed result according to a logic level of the third bit line and the reference voltage;
a fourth sense amplifier, arranged for generating a fourth sensed result according to a logic level of the fourth complementary bit line and the reference voltage; and
a second logic circuit, arranged for generating a second logic output according to the third sensed result and the fourth sensed result;
wherein:
when the memory array operates in the dual-port SRAM mode, the third sensed result indicates the second logic value stored at the first terminal of the second data storage element, in response to selection of the first word line during the read operation, and the fourth sensed result indicates the second complementary logic value stored at the second terminal of the second data storage element, in response to selection of the second word line during the read operation; and
when the memory array operates in the BCAM mode, during the search operation, the second logic output indicates whether the logic level of the first word line matches the second logic value, and whether the logic level of the second word line matches the second complementary logic value.

11. The memory array according to claim 10, wherein when the memory array operates in the BCAM mode and performs the search operation, the third bit line and the fourth complementary bit line are pre-charged to the high logic level at first.

12. The memory array according to claim 11, wherein:
when the memory array operates in the BCAM mode, during the search operation,
if the second logic value, the second complementary logic value, the first word line, and the second word line are logical high, logical low, logical high, and logical low respectively, then a voltage level of the third sensed result and a voltage level of the fourth sensed result are both logical high; and
if the second logic value, the second complementary logic value, the first word line, and the second word line are logical high, logical low, logical low, and logical high respectively, then a voltage level of the third sensed result is logical high and a voltage level of the fourth sensed result is logical low.

13. The memory array according to claim 10, further comprising a third logic circuit arranged for generating a third logic output according to the second sensed result and the third sensed result.

14. The memory array according to claim 13, wherein when the memory array operates in a ternary content-addressable memory (TCAM) mode and performs the search operation, the first bit line, the second complementary bit line, the third bit line, and the fourth complementary bit line are pre-charged to the high logic level at first.

15. The memory array according to claim 14, wherein when the memory array operates in the TCAM mode, during the search operation, if the first logic value, the first complementary logic value, the second logic value, the second complementary logic value, the first word line, and the second word line are logical high, logical low, logical high, logical low, logical high, and logical low respectively, then a voltage level of the second sensed result and a voltage level of the third sensed result are both logical high.

16. The memory array according to claim 14, wherein when the memory array operates in the TCAM mode, during the search operation, if the first logic value, the first complementary logic value, the second logic value, the second complementary logic value, the first word line, and the second word line are logical high, logical low, logical high, logical low, logical low, and logical high respectively, then a voltage level of the second sensed result is logical low and a voltage level of the third sensed result is logical high.

17. The memory array according to claim 14, wherein when the memory array operates in the TCAM mode, during the search operation, if the first logic value, the first complementary logic value, the second logic value, the second complementary logic value, the first word line, and the second word line are logical low, logical high, logical low, logical high, logical low, and logical high respectively, then a voltage level of the second sensed result and a voltage level of the fourth sensed result are both logical high.

18. The memory array according to claim 14, wherein when the memory array operates in the TCAM mode, during the search operation, if the first logic value, the first complementary logic value, the second logic value, the second complementary logic value, the first word line, and the second word line are logical low, logical high, logical low, logical high, logical high, and logical low respectively, then a voltage level of the second sensed result is logical high and a voltage level of the third sensed result is logical low.

19. The memory array according to claim 14, wherein when the memory array operates in the TCAM mode, during the search operation, if the first logic value, the first complementary logic value, the second logic value, the second complementary logic value, the first word line, and the second word line are logical low, logical high, logical high, logical low, logical high, and logical low respectively, then a voltage level of the third sensed result and a voltage level of the fourth sensed result are both logical high.

20. The memory array according to claim 14, wherein when the memory array operates in the TCAM mode, during the search operation, if the first logic value, the first complementary logic value, the second logic value, the second complementary logic value, the first word line, and the second word line are logical low, logical high, logical high, logical low, logical low, and logical high respectively, then a voltage level of the third sensed result and a voltage level of the fourth sensed result are both logical high.
